(19) United States
(12) Patent Application Publication
(10) Pub. No.: US 2019/0237599 A1
(43) Pub. Date: Aug. 1, 2019

(54) METHOD FOR PRODUCING ELECTRICAL CONTACTS ON A COMPONENT

(71) Applicant: Fraunhofer-Gesellschaft Zur Forderung Der Angewandten Forschung e.v., Munich (DE)

(72) Inventors: Markus Glatthaar, Horben (DE); Jonas Bartsch, Freiburg (DE); Mathias Kamp, Freiburg (DE); Rukmangada Rohit, Freiburg (DE)

(21) Appl. No.: 16/332,916

(22) PCT Filed: Sep. 12, 2017
(86) PCT No.: PCT/EP2017/072874

§ 371 Date: Mar. 13, 2019

(30) Foreign Application Priority Data
Sep. 16, 2016 (DE) 10 2016 217 789.3
Feb. 24, 2017 (DE) 10 2017 203 038.0

(51) Int. Cl. H01L 31/0224; H01L 31/0216

(52) U.S. Cl. CPC H01L 31/022425; H01L 31/022475; H01L 31/0747; H01L 31/02167; H01L 31/022466

(57) ABSTRACT

The present invention relates to a method for producing one or more electrical contacts on a component, comprising the following steps:—providing a component which has a front and a rear, an outer layer of a transparent, electrically conductive oxide (TCO) or a self-passivating metal or semiconductor being present on the front and/or rear;—applying a structured, electrically conductive seed layer, the application of the seed layer taking place non-galvanically;—galvanically depositing at least one metal on the seed layer.

The present invention relates to a process for producing electrical contacts (for example in the form of electrical conductor tracks) on an assembly, especially an electrical component, for example a solar cell or a light-emitting diode, or a precursor of a printed circuit board. The present invention further relates to devices obtainable via this process.

A requirement for the use of many assemblies is that electrical contacts, especially in the form of electrical conductor tracks, are installed thereon. The electrical contacts serve, for example, to lead current away from the assembly or tap voltage from the assembly or to establish an electrical connection between electrical components present atop the assembly. If the assembly is a solar cell, for example, the photocurrent generated in this semiconductor component via the photovoltaic effect can be led off via the electrical contacts. Alternatively, the assembly may, for example, be a precursor of a printed circuit board (PCB) which is ultimately converted to a printed circuit board by the application of conductor tracks.

In a known and customary process, a paste comprising silver particles is applied to the assembly and then treated at a sufficiently high temperature to bring about sintering of the silver particles. For this purpose, temperatures of at least 800° C. may be required. However, such high temperatures are unacceptable for many assemblies.

A heterojunction solar cell, for example a silicon heterojunction solar cell (SHJ solar cell), is an example of an electrical component unsuitable for installation of electrical contacts at relatively high temperatures. The SHJ solar cell is a wafer-based crystalline silicon solar cell with an emitter and a back- or front-surface field of amorphous silicon. The starting material used for this purpose is crystalline, especially monocrystalline, silicon that has been n- or p-doped (base doping). A very thin (about 1 to 10 nm) intrinsic (undoped) amorphous silicon layer is first applied thereto on both sides. This is followed, on one side, by the application of a likewise very thin (about 10 to 50 nm) doped amorphous silicon layer having the opposite doping type (n- or p-type) from the base doping (amorphous emitter layer). On the other side is applied a thin (10 to 50 nm) amorphous silicon layer having the corresponding doping type to the base doping (back- or front-surface field). Finally, a transparent conductive oxide (TCO), for example indium tin oxide (ITO) of thickness 50-100 nm, is applied. Such a TCO layer at 25° C. typically has a sheet resistance of not more than 300Ω. The construction and working of heterojunction solar cells are described, for example, by S. De Wolf et al., Green, Vol. 2 (2012), p. 7-24.

In order to avoid unwanted crystallization in the amorphous silicon layers of the SHJ solar cell, temperatures of more than 250° C. should be avoided.

For other solar cell types as well or other electrical components, such as light-emitting diodes, the installation of electrical contacts with minimum thermal stress is desirable.

The use of sufficiently small silver nanoparticles can lower the sinter temperature of silver pastes to below 200° C. However, a disadvantage here is that the pastes cannot be stored since the sintering process proceeds gradually even at room temperature, and that silver nanoparticles constitute a considerable risk to health. Moreover, the costs of nanoparticles are much higher than for large particles or galvanically deposited metals.

Also known is the use of pastes containing organic binders, for example thermally crosslinking resins, and silver particles in flake form. The resin forms a matrix that holds the flakes together and establishes the bond strength to the outer layer of the electrical component (for example a layer of a transparent, electrically conductive oxide (TCO) such as ITO). But this achieves much thermal conductivity than with thermally sintered pastes. As a result, more silver is required and the shadowing of the front side of the solar cell by the conductor tracks is increased.

Alternatively, the conductor tracks can be applied galvanically (i.e. by electroplating). This achieves very good electrical conductivity of the conductor tracks. But the surface has to be printed with a mask of electroplating lacquer as a negative of the conductor track pattern. After the galvanic deposition, the lacquer has to be removed in a chemical bath. But the necessity of this lacquer mask makes this process very costly owing to the material consumption and the necessary wastewater cleaning. Moreover, the bond strength of the galvanically applied metal layer on a TCO layer (i.e. a layer of a transparent, electrically conductive oxide such as ITO) is unsatisfactory in some cases.

In the case of particularly high-value assemblies, a thin metal layer or a metal layer stack is first applied over the whole area of the workpiece. Atop that is applied a photoresist, for example, which is structured by photolithography in the form of a negative mask of the conductor tracks to be created. Alternatively, the negative mask is applied in already structured form (for example by means of an inkjet). The surface which has not been coated with the lacquer is thickened with copper by electroplating and the copper is optionally protected from oxidation by an additional silver layer. Subsequently, the lacquer is removed in a chemical bath and the metal is etched in the previously lacquer-coated regions. A corresponding metallization process is described, for example, in U.S. Pat. No. 8,399,287.

US 2014/0295614 describes a process for metallization of backside contact solar cells. The vapor-deposited aluminum seed layer can be activated over the whole area by a zincate step. Subsequently, a local barrier layer can be applied. After the galvanic deposition, the barrier layer has to be removed and the activated aluminum seed layer etched.

In the case of printed circuit boards (PCBs) made of plastic as well, for lack of thermal stability of the board material, it is not possible to print conductor tracks of sinterable metal particles. Conductor tracks made of silver flakes in a resin matrix are an option only in exceptional cases owing to the high costs, lack of conductivity and lack of suitability for soldering processes for coupling of the electrical assemblies.

It is an object of the present invention to apply electrical contacts, for example electrical conductor tracks, to an assembly via a process that keeps thermal stress on the assembly at a low level, avoids the use of masks (e.g. lacquer masks) and is performable with maximum efficiency.

The object is achieved by a process of producing one or more electrical contacts on an assembly, comprising the following steps:
providing an assembly having a front side and a backside, wherein an outer layer of a transparent, electrically conductive oxide (TCO) or a self-passivating metal or semiconductor is present on the front side and/or the backside,
applying a structured, electrically conductive seed layer to defined regions of the outer layer, said seed layer being applied non-galvanically,
galvanically depositing at least one metal on the seed layer.

As will be described in more detail hereinafter, the process of the invention uses an assembly with a specific outer layer (TCO layer or layer of self-passivating metal or semiconductor), on which galvanic deposition of metals, for example copper, is impossible or at least significantly inhibited. If, however, a structured seed layer with good electrical conductivity is applied to the outer layer in defined regions via non-galvanic deposition (e.g. via a printing process), this structured seed layer (but not the exposed outer layer) can be galvanically coated very efficiently, and the electrical contact resistance between the TCO layer or the layer of self-passivating metal or semiconductor and the seed layer applied thereto is still sufficiently small to effectively lead current away from the assembly (e.g. a solar cell) via the galvanically deposited metal layer.

The outer layer of a self-passivating metal or semiconductor is also referred to hereinafter as self-passivating outer layer.

Coatings of a self-passivating metal or semiconductor, even at room temperature, form a thin oxide film on their surface. The presence of this oxide film prevents or at least inhibits the galvanic deposition of a metal on the self-passivating metal or semiconductor. The galvanic deposition of standard metals such as copper even on transparent conductive oxides (TCOs), for example indium tin oxide (ITO), may be inhibited, especially at low applied voltage.

Coatings of TCOs or self-passivating metals or semiconductors thus constitute surfaces on which galvanic metal deposition can be inhibited. However, it has been found that these surfaces that are difficult to coat galvanically do in fact have a relatively low electrical contact resistance with respect to electrically conductive layers applied thereto which in turn can be efficiently coated by electroplating. On defined areas of the surface of a self-passivating metal or semiconductor or of a TCO, representing a material which is difficult to coat by electroplating, a material is applied (e.g. by means of a printing process) which can be efficiently coated by electroplating. This applied material functions as seed layer for the subsequent galvanization step. No mask is needed for applying the structured, electrically conductive seed layer. The application of the seed layer can be effected at relatively low temperatures, such that thermal stress on the assembly (for example an amorphous silicon layer in a silicon hetero-cell or the board material of a printed circuit board) is minimized.

In the subsequent galvanization step, the metal is deposited exclusively or at least predominantly on the structured seed layer. The application of a mask to the self-passivating metal or semiconductor or to the TCO is not required since galvanic deposition on these materials does not occur or is at least inhibited. Thus, after the galvanization step, a structure is obtained, for example in the form of one or more conductor tracks, that enables efficient electrical contact connection of the electrical component or the formation of an effective circuit structure of a printed circuit board.

The electrical contacts are in the form, for example, of one or more conductor tracks. The electrical contacts serve, for example, to lead current off from the assembly or to tap voltage from the assembly or to establish an electrical connection between electrical components present on the assembly.

As already set out above, the process of the invention includes firstly the provision of an assembly having a front side and a backside, wherein there is an outer layer of a transparent, electrically conductive oxide (TCO) or a self-passivating metal or semiconductor on the front side and/or backside.

The assembly is, for example, an electrical component (e.g. an optoelectronic component or a semiconductor component) or a precursor thereof.

The assembly on which the electrical contacts are to be installed may also be the precursor of a printed circuit board. The precursor of the printed circuit board preferably contains a plastic (especially an electrically nonconductive plastic) which may optionally also be reinforced by fibers, and the outer layer of the transparent, electrically conductive oxide (TCO) or the self-passivating metal or semiconductor is then preferably present atop said plastic. The precursor of the printed circuit board may, for example, be a flexible film or alternatively a rigid or stiff sheet.

A preferred electrical component is, for example, a solar cell, a diode (e.g. a light-emitting diode) or a display screen, especially a flat display screen (flat panel display), e.g. a liquid-crystal display (LCD).

In the case of a solar cell, the front side is the illuminated side of the assembly, i.e. that facing the radiation source. By the process of the invention, it is possible to apply the electrical contacts, for example, on the front side or on the backside (for example in the case of an exclusively backside-contacted solar cell) or on each side of the assembly.

The electrical component to which the electrical contact is applied need not yet be in its final form, but typically already contains those components that are essential to its function (for example achievement of the photovoltaic effect). Alternatively, the assembly to which the electrical contact is applied may be a precursor of an electrical assembly, and the further components required for the achievement of its mode of function are added only after the application of the electrical contact.

In the context of the present invention, a solar cell is understood to mean a semiconductor component that shows a photovoltaic effect under the action of radiation energy, generally sunlight.

Preferably, the solar cell is a silicon solar cell.

In a preferred embodiment, the assembly is a heterojunction solar cell, especially a silicon heterojunction solar cell (SHJ solar cell) or a precursor thereof.

The solar cell may also be a solar cell contacted exclusively via its backside. In these solar cells, the electrical contacts might be in the form of an interdigital structure.

The process of the invention is of particular interest for crystalline silicon solar cell types that have a conductive layer having a conductivity that has to be further improved by conductor tracks applied in metallic form at least on one of the two surfaces of a crystalline silicon substrate that serves as base material for the solar cell.

These include, for example, solar cell types having, on at least one side of the crystalline silicon that functions as base material, an optically transparent, electrically conductive coating that suppresses the recombination of electron-hole pairs on the correspondingly coated surface of the crystalline silicon wafer.

These especially include silicon heterojunction solar cells (SHJ) in which the passivating layers consist of amorphous silicon. Alternatively, the surface may consist of a through-tunnelable silicon dioxide layer (which is thus likewise conductive at right angles to the layer), to which a conductive polysilicon layer, a silicon carbide layer or a conductive metal oxide, for example molybdenum oxide, tungsten oxide, nickel oxide or titanium oxide, is subsequently applied. Since the conductivity parallel to the surface of all these layers is very low, it is preferred to additionally apply a high-conductivity TCO layer (e.g. an ITO layer) to the recombination-suppressing layer system. Since, however, even in the case of application of a TCO layer, conductivity parallel to the surface is too low to be able to efficiently remove the current, metallic conductor tracks additionally have to be applied to the surface.

The process of the invention is of excellent suitability for solar cells as assembly, especially for the abovementioned solar cell types, for example an SHJ solar cell, since it does not need a high-temperature step for sintering of the metal layers applied and it is possible to dispense with organic masks.

SHJ solar cells are commercially available or can be produced via processes known to those skilled in the art.

As already mentioned above, particular electrical components, for example SHJ solar cells, light-emitting diodes or LCDs (liquid-crystal displays), frequently contain one or more layers of a transparent, electrically conductive oxide (TCO) as electrode. In these cases, the TCO layer is thus already an integral constituent of the electrical component. The substance class of the TCOs and the use of TCO layers for semiconductor components are known to those skilled in the art; see, for example, Clark I. Bright, chapter 7 (“Review of Transparent Conductive Oxides (TCO)”) in 50 Years of Vacuum Coating Technology and the Growth of the Society of Vacuum Coaters, eds.: Donald M. Mattox and Vivienne Harwood Mattox, Society of Vacuum Coaters, 2007 (ISBN 978-1-878068-27-9) and A. Stadler, Materials, 2012, 5, p. 661-683. Frequently, in these electrical components, the TCO layer is already present as the outermost layer (“outer layer”) of the component. In these cases, it is possible in the context of the process of the invention to apply the electrically conductive seed layer (for example in the form of one or more conductor tracks) directly to said TCO outer layer of the electrical component.

Illustrative TCOs for the TCO outer layer are indium tin oxide (“ITO”), aluminum-doped zinc oxide (“AZO”), fluorine-doped tin oxide (“FTO”), boron-doped zinc oxide or hydrogen-doped indium oxide. TCO coatings may be obtained, for example, by physical or chemical vapour phase deposition.

The TCO layer at 25° C. typically has a sheet resistance, determined via the four-point method, in the range from 10Ω to 1000Ω, more preferably 50Ω to 300Ω. Preferably, the TCO layer has this sheet resistance across its entire area. Even though TCO layers have a relatively low sheet resistance, the galvanic deposition of metals such as copper on such TCO layers, for example an ITO layer, is inhibited compared to deposition on surfaces of metals, especially at low applied voltage.

As an alternative to an outer layer of a transparent, electrically conductive oxide (i.e. a TCO layer), the assembly may have an outer layer of a self-passivating metal or a self-passivating semiconductor.

As is known to the person skilled in the art, the self-passivating metals or semiconductors are those metals or semiconductors that can spontaneously form a passivating, very thin oxide layer under air at room temperature (25° C.). Suitable self-passivating metals are especially aluminum, titanium, nickel, chromium or zinc, or an alloy of one of these metals. A preferred self-passivating semiconductor is silicon.

On the front side and/or backside of the assembly, one may apply just one layer of a self-passivating metal or semiconductor which then already forms the outer layer. Alternatively, it is also possible to apply two or more layers of self-passivating metals or semiconductors to the assembly. The outermost of these layers is then the outer layer.

If the assembly (for example a solar cell, especially an SHJ solar cell) contains a TCO layer, a layer of a self-passivating metal or semiconductor may be present directly atop said TCO layer. This either already forms the outer layer or, alternatively, one or more additional layers of self-passivating metals or semiconductors are applied. In addition, it is also possible that there is at least one layer of a non-self-passivating metal (e.g. copper or silver or an alloy of one of these metals) atop the TCO layer, and there are one or more layers of self-passivating metals or semiconductors atop said non-self-passivating metal layer.

In order to achieve the best possible compromise between high conductivity and good adhesion on the TCO layer, it may be preferable that at least two layers of a self-passivating metal or semiconductor are applied, where the metal or semiconductor of the first self-passivating layer is titanium, nickel, chromium or zinc or an alloy of one of these metals or silicon, and the metal of the self-passivating second layer is aluminum. The first self-passivating layer may be applied directly to the TCO layer. Alternatively, there may be at least one layer of a non-self-passivating metal (e.g. copper or silver or an alloy of one of these metals) between the first self-passivating layer and the TCO layer. The self-passivating aluminum layer may already constitute the outer layer. Optionally, a further layer of a self-passivating metal or semiconductor (e.g. titanium, nickel, chromium or zinc or an alloy of one of these metals or silicon) may be applied and hence form the outer layer. If there are two or more layers of self-passivating metals or semiconductors, these self-passivating layers may be directly successive, or they may be separated from one another by interlayers, for example by what are called diffusion barrier layers (e.g. palladium layers) or layers of non-self-passivating metals (e.g. Cu or Ag layers).

For example, a titanium layer and then an aluminum layer is applied to the TCO layer of the assembly or to a layer of a non-self-passivating metal (e.g. copper or silver or an alloy of one of these metals) present, for example, atop the TCO layer of the assembly, in which case the aluminum layer constitutes the outer layer. Alternatively, it is also possible to apply a titanium layer, then an aluminum layer and then another titanium layer to the TCO layer of the assembly or to a layer of a non-self-passivating metal (e.g. copper or silver or an alloy of one of these metals) present, for example, atop the TCO layer of the assembly, in which case the titanium layer constitutes the outer layer. As already mentioned above, there may optionally be an interlayer, for example a diffusion barrier layer (e.g. a palladium layer) between a titanium layer and an aluminum layer.

A coating of a self-passivating metal or semiconductor may be applied to the assembly via known methods. The outer layer of the self-passivating metal or semiconductor may be obtained, for example, via a physical vapour phase deposition (e.g. sputtering, also referred to as cathode atomization), a chemical vapour phase deposition (e.g. plasma-enhanced vapour phase deposition PECVD) or by applying a foil of the self-passivating metal or semiconductor. These coating methods lead only to minor thermal stress on the assembly.

If the assembly is the precursor of a printed circuit board, the starting material may, for example, be a prepreg to which a foil of the self-passivating metal, preferably an aluminum foil, is applied (e.g. bonded).

The front side and/or backside of the assembly is preferably covered to an extent of at least 50% of its area, more preferably to an extent of at least 80% of its area or even completely with the outer layer formed from the TCO or the self-passivating metal or semiconductor.

Preferably, the outer layer of the assembly has a thickness of ≤25 μm, more preferably ≤15 μm, even more preferably ≤1.0 μm or even less than 500 nm. If the assembly is an electrical component, especially a semiconductor component, for example a solar cell or a diode, it may even be preferable that the thickness of the outer layer is not more than 200 nm, more preferably not more than 100 nm, e.g. 5-100 nm or 5-50 nm. Preferably, the outer layer has the above-specified layer thickness over at least 90% of its area, more preferably over 95% of its area. The layer thickness can be determined via standard methods, for example by microscopic measurement in cross section.

A layer of self-passivating metal or semiconductor automatically forms a thin oxide layer under air on its surface. This passivating oxide layer prevents or at least inhibits galvanic metal deposition. This spontaneous oxide formation can optionally be assisted by suitable measures (e.g. contacting with an oxidizing medium, for example ozone), in order to bring about more homogeneous formation of the thin oxide layer. It is also possible to chemically modify the passivating surface layer by suitable treatment (for example formation of a passivating nitride or oxynitride surface layer). With regard to a very simple and efficient process configuration, however, it is preferable that the layer of self-passivating metal or semiconductor, apart from the formation of oxide under air caused by the self-passivation, optionally assisted by treatment with ozone or UV exposure at temperatures below 200° C., is not subjected to any other chemical modification prior to the application of the seed layer.

Preferably, the contact resistance (at 25° C.) between the TCO layer or the layer of self-passivating metal or semiconductor and the seed layer applied thereto should be less than 50 mΩcm², more preferably less than 10 mΩcm², even more preferably less than 5 mΩcm² or less than 1 mΩcm². Contact resistance can be determined by the transfer line method (also called transfer length method or transfer length measurement). In this method, contact resistance is measured using a suitable test specimen.

As already set out above, in a further step of the process of the invention, a structured, electrically conductive seed layer is applied to defined regions of the outer layer (i.e. the layer of the transparent, electrically conductive oxide (TCO) or the layer of the self-passivating metal or semiconductor), said seed layer being applied by non-galvanic means.

This electrically conductive seed layer is not applied via electroplating, but then serves as substrate for metal coating in a subsequent galvanic deposition step. As the person skilled in the art is aware, the term “seed layer” refers to a thin layer that functions as crystallization seed and adhesion substrate for the galvanic deposition of a metal.

Preferably, the structured, electrically conductive seed layer is applied in the form of one or more conductive tracks, meaning that the electrically conductive seed layer, in terms of its arrangement on the outer layer, is already structured such that it corresponds to the arrangement of the electrical contacts to be formed.

As is common knowledge to the person skilled in the art, galvanic deposition is a method in which the substrate to be coated is contacted with an electrolytic bath typically containing a salt of the metal to be deposited, and the metal is deposited on the substrate by applying an external current source. Since galvanic deposition on a TCO layer or a layer of self-passivating metal or semiconductor is at least inhibited, the seed layer is applied via a non-galvanic deposition.

The structured seed layer may be mono- or multilaminar. If the seed layer is multilaminar, it is formed from two or more superposed laminas, where each lamina may have been manufactured from one or more of the materials mentioned hereinafter and may be obtained by one or more of the process steps mentioned hereinafter. Adjoining laminas preferably have a different composition.

Application of the seed layer to defined regions of the outer layer is effected, for example, via a printing method, especially screenprinting, inkjet printing, flexographic printing or aerosol printing, a laser transfer method (also referred to as “laser induced forward transfer” (LIFT)) or an electroless plating (e.g. zinc deposition by the zincate method and/or deposition of electroless nickel). These coating methods are known to those skilled in the art.

Components for a seed layer that have sufficiently high electrical conductivity and enable galvanic metal deposition on the seed layer are known to those skilled in the art. The electrically conductive component present in the seed layer is, for example, one or more metals (e.g. copper or a copper alloy, a precious metal or a precious metal alloy such as silver or a silver alloy, nickel or a nickel alloy (e.g. a nickel-vanadium alloy), indium or an indium alloy, tin or a tin alloy, cobalt or a cobalt alloy), one or more electrically conductive polymers (e.g. poly-3,4-ethylenedioxythiophene (PEDOT) or a mixture of PEDOT and polystyrenesulfonate (PEDOT:PSS)), one or more electrically conductive carbon materials (e.g. graphene, graphene oxide, carbon nanotubes, graphite, carbon black), or a mixture of at least two of these components.

The electrically conductive component of the seed layer may take the form, for example, of particles (e.g. metal particles or carbon particles). These electrically conductive particles may be embedded into an organic or inorganic support material, for example an organic polymer. The organic polymer may be a thermoplastic or alternatively a crosslinkable or, after curing, a crosslinked polymer. For example, the electrically conductive particles of the seed layer are present in a synthetic resin that cures (for example by thermal treatment and/or UV treatment) after the application of the seed layer via the printing method. Suitable organic or inorganic carrier materials for electrically conductive particles that can be used in a printing method are known to those skilled in the art.

The seed layer can also be applied by a laser transfer method (“laser induced forward transfer” LIFT). The LIFT method is known to the person skilled in the art. In this method, the seed layer, preferably of nickel, silver or copper (more preferably of nickel), is first applied to a transparent substrate, for example by means of physical vapour phase deposition PVD. The substrate is then brought into contact with the outer layer of the assembly, or at least positioned with a distance of less than 1 mm from the outer layer of the assembly, with the seed layer pointing toward the outer layer. Then, by means of laser irradiation, the seed layer is detached from the substrate and transferred to the outer layer of the assembly.

The seed layer can also be applied by electroless plating. As is known to the person skilled in the art, an electroless plating is understood to mean a coating method in which the reduction of the metal to be deposited (by contrast with a galvanic deposition) proceeds without employment of an external current source. Preferably, electroless plating is used to deposit nickel (also referred to as “electroless nickel”) and/or zinc (for example via the zincate method). In a preferred embodiment, the outer layer (preferably a self-passivating aluminum layer) is first treated in defined regions with a zincate solution to form a zinc layer, and then the electroless deposition of the chemical nickel layer is effected on these regions provided with a zinc layer. Suitable electrolyte solutions for the electroless deposition of nickel are known to those skilled in the art. The electrons required for reduction of the nickel ions can be produced directly in the electrolyte solution by a chemical reaction, for example by the reducing agent sodium hypophosphite. The electrolyte solution also contains a nickel salt, for example nickel sulfate. The nickel deposition is autocatalytic. Since phosphorus is also incorporated, a nickel-phosphorus alloy is obtained. The zinc-coating of defined regions of the aluminum layer can be effected, for example, by applying the zincate solution with a die of defined geometry.

In the regions in which the seed layer is applied to the outer layer, this application (for example by a LIFT method or by electroless application of zinc and/or nickel) may remove the thin oxide layer that resulted from the self-passivation.

Preferably, the structured seed layer is produced without using a mask.

If the structured seed layer is multilaminar, the applying of the structured seed layer may comprise the following steps:
applying an electrically conductive metal layer S1 to the outer layer (i.e. the TCO layer or the self-passivating layer) via gas phase deposition,
applying an electrically conductive layer S2 to defined regions of the metal layer S1 by a printing method, especially screenprinting, inkjet printing, flexographic printing or aerosol printing, a laser transfer method or an electroless plating (e.g. “electroless nickel”, or zinc via the zincate method),
removing the exposed regions of the metal layer S1 that were not covered by the layer S2.

The removing of the exposed regions of the metal layer S1 that were not covered by layer S2 exposes the underlying TCO layer or self-passivating layer. In the subsequent galvanization step, as already stated above, there is then selective metal deposition on the seed layer, while metal deposition on the exposed TCO layer or self-passivating layer does not take place or is at least inhibited.

The electrically conductive metal layer S1 might be applied to the TCO layer or the self-passivating layer via a physical vapour phase deposition (e.g. sputtering) or a chemical vapour phase deposition (e.g. a plasma-enhanced vapour phase deposition PECVD). The electrically conductive metal layer S1 preferably has a relatively small thickness, for example a thickness in the range of 5-100 nm, more preferably 5-75 nm, even more preferably 5-50 nm. The electrically conductive metal layer S1 preferably contains one or more of the following metals: copper or a copper alloy, silver or a silver alloy, tin or a tin alloy, cobalt or a cobalt alloy, nickel or a nickel alloy (e.g. a nickel-vanadium alloy). The metal layer S1 obtained by a vapour phase deposition may be mono- or multilaminar. A multilaminar metal layer S1 can be obtained, for example, by conducting two or more vapour phase depositions in succession.

With regard to suitable electrically conductive components for layer S2, reference may be made to the remarks above. The electrically conductive layer S2 therefore contains, for example, one or more metals (e.g. copper or a copper alloy, a precious metal or a precious metal alloy such as silver or a silver alloy, nickel or a nickel alloy, indium or an indium alloy, tin or a tin alloy, cobalt or a cobalt alloy), one or more electrically conductive polymers (e.g. poly-3,4-ethylenedioxythiophene (PEDOT) or a mixture of PEDOT and polystyrenesulfonate (PEDOT:PSS)), one or more electrically conductive carbon materials (e.g. graphene, graphene oxide, carbon nanotubes, graphite, carbon black), or a mixture of at least two of these components.

Prior to the galvanic deposition of a metal on the seed layer, the exposed regions of the metal layer S1 that were not covered by the layer S2 are removed. This is effected by methods known to those skilled in the art, for example by etching or electrochemical oxidation. In the case of electrochemical oxidation, by applying a suitable potential, the metal is oxidized (i.e. converted to metal cations) and the metal cations go into solution in an adjoining liquid electrolyte. The removing of the exposed regions of the metal layer S1 that were not covered by the layer S2 exposes the underlying TCO layer or self-passivating layer.

Preferably, the seed layer has a thickness of ≤20 μm, more preferably ≤8 μm, even more preferably ≤2 μm. The minimum thickness of the seed layer is, for example, 100 nm. Preferably, the seed layer has the above-specified layer thickness over at least 80% of its area, preferably over its entire area. The layer thickness can be determined via standard methods, for example by microscopy measurement in cross section.

As set out above, in a further step of the process of the invention, at least one metal is galvanically deposited on the seed layer.

The galvanically deposited metal is preferably copper or a copper alloy, nickel or a nickel alloy or a precious metal such as silver or a silver alloy. The galvanically deposited layers preferably have a thickness of 1-100 μm, preferably 1-20 μm, more preferably 2-15 μum. The layer thickness can be determined via standard methods, for example by microscopy measurement in cross section.

For the galvanic deposition, the seed layer is contacted with an electrolytic bath containing a salt of the metal to be deposited. Typically also immersed into the electrolytic bath is an auxiliary electrode, for example a copper anode (“sacrificial anode”) or a titanium electrode. The counterelectrode used is the electrically conductive seed layer. If the seed layer is supplied with a suitable negative (i.e. cathodic) electrical potential, the metal ions are reduced and the metal is deposited on the seed layer.

The galvanic deposition can be effected by means of direct current or by means of pulsed current. As described in more detail hereinafter, the use of a pulsed current of changing sign can further improve the selective deposition of the metal on the seed layer. A pulsed current of changing sign has alternating negative (cathodic) and positive (anodic) current pulses.

As already mentioned above, the galvanic deposition of the metal on the TCO layer or the layer of the self-passivating metal or semiconductor is at least significantly inhibited. For the galvanic deposition step, it is therefore unnecessary to protect those regions of the outer layer that are not covered by the structured seed layer by means of a mask. The regions of the TCO layer or of the layer of the self-passivating metal or semiconductor that are still exposed after the application of the seed layer therefore remain unmasked even during the galvanic deposition and can come into contact with the electrolytic bath.

Even though the galvanic deposition on the outer layer of the assembly is at least inhibited, it has been found in the context of the present invention that, on application of a negative electrical potential, the current density at the surface of this outer layer can still be sufficiently high for the deposition of relatively small metal crystallites (for example owing to a very small thickness of the passivating oxide layer or owing to structural defects in this passivating oxide layer).

In a preferred embodiment, the galvanic deposition of the metal is effected by means of pulsed current. In the pulsed current method, a current that varies with time is used, meaning that the seed layer is supplied with a potential that varies with time.

In a particularly preferred embodiment, a pulsed current of changing sign is used, i.e. one that has alternately negative (cathodic) and positive (anodic) current pulses. If the seed layer is supplied with a negative potential (i.e. subjected to a cathodic current pulse), there is galvanic deposition of the metal on said seed layer. To a small degree, in this time interval, there can also be metal deposition on the exposed regions (that are therefore in contact with the electrolytic electrolyte) of the TCO layer or of the layer of self-passivating metal or semiconductor. If the electrical potential changes sign, such that the seed layer is now supplied with a positive potential, already deposited metal is dissolved. However, this dissolution proceeds primarily at the cost of the small amount of metal that has been deposited on the exposed outer layer of the assembly, whereas the dissolution of the metal deposited on the seed layer is not a significant consideration.

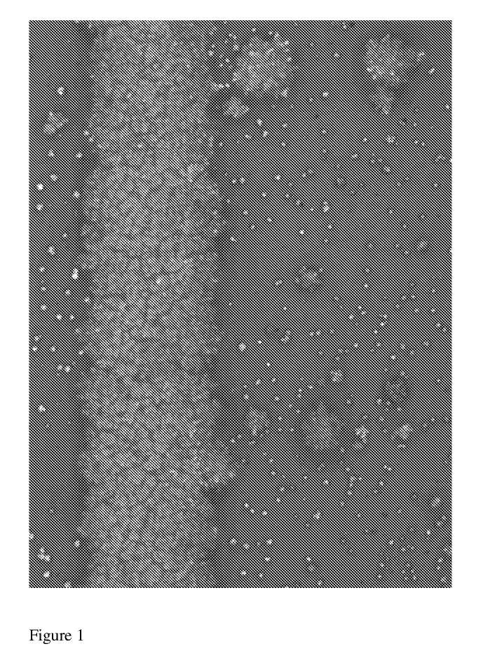

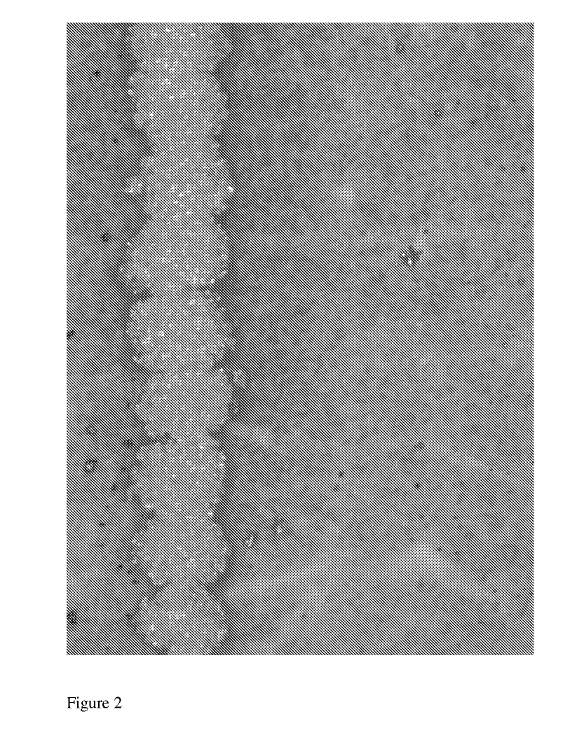

FIG. 1 shows, in a microscope image, in top view, the surface of an outer layer of a self-passivating metal on which there is a seed layer in the form of a stripe and a galvanically deposited metal coating atop said seed layer, without use of pulsed current for the galvanic deposition. Although the galvanic metal deposition on the surface of the self-passivating metal is inhibited, owing to the small thickness or owing to defects in the thin oxide film, there is nevertheless a certain degree of galvanic deposition of metal crystallites on the outer layer. FIG. 2 shows, in a microscope image, in top view, the surface of an outer layer of a self-passivating metal on which there is a seed layer in the form of a stripe and a galvanically deposited metal coating atop said seed layer. The galvanic deposition was effected using pulsed current with alternating cathodic and anodic current pulses. As shown by FIG. 2, the metal is deposited virtually exclusively on the seed layer in the form of a stripe. Barely any metal deposits are apparent on the exposed outer layer.

Given suitable choice of the time intervals and of the positive and negative voltages/currents, the seeds in regions without seed layer will dissolve completely again, while galvanically deposited metal that increases constantly from an interval with negative voltage on the workpiece to the next will remain in the regions with seed layer. Surprisingly, the parameter space suitable for this purpose is very large. The intervals in which the seed layer is supplied with a negative potential (i.e. the cathodic current pulses) can last up to 10 s, but the duration thereof is preferably less than 500 ms, more preferably less than 100 ms, especially preferably less than 10 ms. The intervals of positive potential on the seed layer with respect to the electrolytic bath (i.e. the anodic current pulses) are preferably shorter than the intervals of negative potential, more preferably less than half as long, especially preferably less than a quarter as long. Preferably, during the intervals in which the seed layer is supplied with negative potential, a maximum current amplitude density of 1-60 A/cm², based on the area of the seed layer, is defined. Preferably, the maximum current amplitude in the case of negative potential of the seed layer with respect to the electrolytic bath should be chosen to be at most as high as in the case of positive potential. More preferably, the current amplitude in the case of negative potential of the seed layer is chosen to be half as high as in the case of positive potential. Further preferably, the current amplitude in the case of positive potential is chosen to be sufficiently high that the maximum voltage amplitude limits the current.

For the maximum voltage amplitudes, the following preferably applies: anodic voltage amplitude (which preferably is >2 V, more preferably >5 V, especially preferably >9 V) at the seed layer relative to the electrolytic bath is preferably higher than the cathodic voltage amplitude (which preferably is <3 V, more preferably <2 V, even more preferably <1.7 V).

If the galvanic deposition of the metal is conducted by means of pulsed current with changing sign, in the time interval in which the seed layer is supplied with a positive potential, there can be not only dissolution of already deposited metal but also oxidation of the material of the outer layer, especially if the outer layer is a layer of a self-passivating metal or semiconductor such as aluminum or silicon. In the regions in which the exposed outer layer comes into contact with the electrolytic bath, the self-passivating outer layer can become increasingly oxidized. In the self-passivating layer, the oxidation proceeds from the surface inward and, ultimately, oxidic regions that extend across the entire thickness or height of the outer layer can be obtained within this layer. If the thickness chosen for the outer layer is sufficiently small, for example 5-100 nm or 5-50 nm, the result is visually transparent oxidic regions. Visual transparency is advantageous particularly for solar cells, for example SHJ solar cells.

In a preferred embodiment, therefore, the assembly is a solar cell (especially an SHJ solar cell), on the front side and/or backside of which there is an outer layer of a self-passivating metal or semiconductor, preferably aluminum, titanium, nickel, chromium, zinc or silicon, the thickness of which is 5-100 nm, more preferably 5-50 nm, and the galvanic deposition is effected by means of pulsed current with changing sign (i.e. with alternating cathodic and anodic current pulses). Preferably, the duration and amplitude of the cathodic and anodic current pulses are chosen such that the self-passivating outer layer forms oxidic regions that extend across the entire thickness or height of the outer layer. The layer of self-passivating metal or semiconductor is applied, for example, via chemical or physical vapour phase deposition (e.g. CVD such as PECVD or sputtering). If the solar cell is an SHJ solar cell, the outer layer of self-passivating metal or semiconductor may be atop the TCO layer on at least one of the two sides of the SHJ solar cell. As already mentioned above, it is also possible that there are two or more layers of self-passivating metals or semiconductors, in which case the outermost of these layers constitutes the outer layer. One of the inner layers of self-passivating metal or semiconductor may be positioned, for example, directly atop the TCO layer.

In a preferred embodiment, the seed layer and the exposed regions of the outer layer that are not covered by the seed layer are subjected to a treatment with a pulsed current, wherein
in a first step, the cumulative charge that flows during the anodic pulses is less than the cumulative charge that flows during the cathodic pulses, and
in a subsequent second step, the cumulative charge that flows during the anodic pulses is greater than the cumulative charge that flows during the cathodic pulses,
   wherein at least the first step of this pulsed current treatment takes place during the galvanic deposition of the metal.

The use of a pulsed current treatment having two different steps (i.e. a first step and a second step that meet the abovementioned conditions) allows even further improvement of the selective deposition of the metal on the seed layer and the oxidation of the exposed regions of the outer layer.

Optionally, both steps of this pulsed current treatment can also take place during the galvanic deposition of the metal in the electrolytic bath. Alternatively, it is also possible that the first step of the pulsed current treatment takes place during the galvanic deposition of the metal in the electrolytic bath, then the seed layer and the exposed regions of the outer layer are transferred from the electrolytic bath to an anodization bath and the second step of the pulsed current treatment is conducted in the anodization bath.

In order to even further optimize the oxidation of the self-passivating metal or semiconductor in the exposed regions (i.e. those not covered by the seed layer) of the outer layer, it may be preferable, after the galvanic deposition of the metal (which was preferably effected using a pulsed current with cathodic and anodic pulses), to conduct a further anodization of the self-passivating metal (e.g. aluminum) or semiconductor in an anodization bath. As is known to the person skilled in the art, anodization is an electrolytic method of producing or thickening oxidic layers on metals or semiconductors. Suitable anodization baths are known to those skilled in the art and contain, for example, sulfuric acid, oxalic acid, citric acid or chromic acid.

Preferably, the anodization is also conducted using a pulsed current with alternating cathodic and anodic pulses. Since, during the anodization, in the course of supply of anodic voltage, a certain degree of dissolution of the metal already galvanically deposited also takes place, the anodization bath inevitably also contains metal ions; preferably, metal ions are additionally added to the bath by adding an appropriate metal salt and/or using a counterelectrode made of the appropriate metal in the bath. In the case of pulsed performance of the anodization, it is thus possible to utilize the cathodic pulses for the deposition of the metal. Preferably, in the case of anodization in the anodization bath, the cumulative charge that flows during the anodic pulses is greater than the cumulative charge that flows during the cathodic pulses.

In the electrolytic bath, there is growth of the galvanically deposited metal layer on the seed layer, and in this phase the anodic pulses prevent parasitic deposition on the rest of the outer layer. In the anodization bath, in the regions in which the outer layer does not have any seed layer with galvanic layer deposited thereon, there is increased transformation of the outer layer to a corresponding oxide layer. The charge that flows during the anodic pulses can be calculated from the integral of the current over the time during which the assembly is supplied with anodic potential. Correspondingly, the charge that flows during the cathodic pulses can be calculated from the integral of the current over the time during which the assembly is supplied with cathodic potential. With regard to the changing sign of the charge that has flowed from anodic to cathodic flow direction, the absolute value of the charge should be used in each case in the comparison of the charges that have flowed.

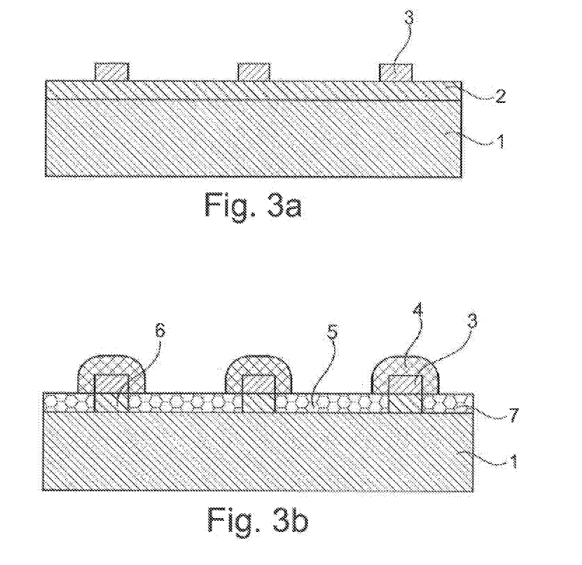

A preferred embodiment using the SHJ solar cell is elucidated in more detail with regard to FIGS. 3a and 3b.

FIG. 3a shows, in schematic cross section, an SHJ solar cell 1, a thin outer layer 2 of a self-passivating metal or semiconductor (e.g. Al, Ti or Si) and a structured seed layer 3 present in defined regions of the self-passivating outer layer 2. The outer layer 2 may be applied, for example, by PECVD and preferably has a thickness in the range of 5-100 nm, more preferably 5-50 nm. The self-passivating outer layer 2 is present atop the TCO layer (not shown in FIG. 1a) of the SHJ solar cell. Alternatively, there may be one or more additional layers (for example a further layer of a self-passivating metal or semiconductor or a layer of a non-self-passivating metal, for example Cu, Ag or Pd) between the TCO layer and the self-passivating outer layer. The construction of an SHJ solar cell 1 has already been described in more detail above and is therefore not shown in detail in FIG. 3a. At the surface of the self-passivating outer layer 2, a very thin passivating oxide film (not shown) will inevitably form. By means of a suitable method (e.g. a printing method such as screen printing, inkjet printing or aerosol printing, a laser transfer method or an electroless plating), an electrically conductive seed layer 3 is applied to defined regions of the self-passivating outer layer 2. As electrically conductive component, the seed layer 3 contains, for example, one or more metals (e.g. copper or a copper alloy, nickel or a nickel alloy, indium or an indium alloy, tin or a tin alloy, a precious metal such as silver or a silver alloy, zinc or a zinc alloy, chromium or a chromium alloy, cobalt or a cobalt alloy), one or more electrically conductive polymers (e.g. poly-3,4-ethylenedioxythiophene (PEDOT) or a mixture of PEDOT and polystyrenesulfonate (PEDOT:PSS)), one or more electrically conductive carbon materials (e.g. graphene, graphene oxide, carbon nanotubes, graphite, carbon black) or a mixture of at least two of these components.

Atop the seed layer 3, a metal 4 is then galvanically deposited using a pulsed current with cathodic (negative) and anodic (positive) current pulses. The resultant structure is shown in schematic form in FIG. 3b. For the galvanic deposition, the seed layer 3 and the exposed regions of the outer layer 2 were contacted with an electrolytic bath. The presence of the outer layer 2 protects the sensitive TCO layer of the SHJ solar cell from the chemically aggressive electrolytic bath. The seed layer 3 was supplied with an electrical potential of periodically changing sign. The metal 4 is essentially deposited only on the seed layer 3 since galvanic metal deposition on the passivated surface of the outer layer 2 is inhibited. In the context of the present invention, however, it has been recognized that there might be minor deposition of metal on the passivated surface of the outer layer 2 as well. The use of a pulsed current with changing sign allows these parasitic metal depositions on the exposed regions of the outer layer 2 to be dissolved again. In addition, in the exposed regions of the outer layer 2 that are therefore in contact with the electrolytic bath, there is oxidation of the metal or semiconductor which proceeds from the outside inward. Ultimately, oxidic regions 5 that extend across the entire thickness of the outer layer 2 form within the outer layer. The regions of the outer layer 2 that are beneath the seed layer 3 remain metallic or semiconductive. As a result, what is obtained is a coating 7 having lateral structuring in which oxidized regions 5 alternate with metallic or semiconductive regions 6. The seed layer 3 is present atop the metallic or semiconductive regions 6 of the laterally structured coating 7 and is fully covered by the galvanically deposited metal layer 4. Owing to the small thickness, the oxidic regions 5 are transparent. Shadow effects that could reduce the efficiency of the solar cell are avoided as a result. Owing to the self-passivation, there may be a thin oxide layer between the metallic or semiconductive regions 6 and the structured seed layer 3 present thereon, if it has not been removed again in these regions for process-related reasons during the application of the seed layer. As already mentioned above, the contact resistance between the metallic or semiconductive region 6 and the seed layer applied thereto is relatively low, and so the current generated via the photovoltaic effect in the solar cell can be removed in an effective manner via the metallic or semiconductive regions 6, the seed layer and the galvanically deposited metal layer. The process can be conducted without using a mask. Significant thermal stress on the assembly is also avoided.

As an alternative to anodization of the exposed regions of the outer layer during and/or after the galvanic deposition, it is also possible in the context of the present invention to remove these exposed regions of the outer layer after the galvanic deposition of the metal by an etching treatment. In this case, openings (i.e. solids-free regions) are created between the metallic or semiconductive regions covered by the seed layer. For example, it is thus possible to create electrical contacts with interdigital structure as required for the backside contact connection of solar cells.

In the case of an etching treatment of the exposed regions of the outer layer for removal of the self-passivating metal or semiconductor as well, it may be preferable to conduct the preceding galvanic deposition using pulsed current with changing sign in order to minimize parasitic metal deposits in the exposed regions of the outer layer. However, the duration and amplitude of the anodic and cathodic current pulses are preferably chosen here so as to minimize oxidation of the outer layer (i.e. only at the surface of the outer layer, and not any deeper oxidation). As a result, the individual conductor tracks remain electrically connected to one another. This is advantageous since all conductor tracks thus grow uniformly in the galvanic deposition process without having to provide every individual track with an external contact.

In the etching treatment, after the galvanic deposition of the metal on the seed layer, the exposed regions of the outer layer are treated with an etching bath. As a result, the outer layer is removed in these regions. After the etching step, regions of self-passivating metal or semiconductor remain on the assembly (e.g. the solar cell or the precursor of the printed circuit board), atop these is a seed layer with the galvanically deposited metal coating, and between these regions of self-passivating metal or semiconductor there are openings (i.e. solids-free regions). In this case too, lateral structuring is created in the outer layer. Suitable etching baths are known to those skilled in the art (e.g. basic or acidic etching baths). In a preferred embodiment, the assembly is supplied with a negative voltage relative to the etching bath. This may be advantageous especially when the assembly, especially a solar cell, for example an SHJ solar cell, contains a TCO layer (e.g. an ITO layer) and this TCO layer is to be exposed by the treatment in the etching bath. The supply of a negative charge to the assembly relative to the etching bath avoids corrosive damage to the TCO layer. The magnitude of the negative charge may vary depending on the metals to be removed in the etching bath. For example, the assembly is supplied with a negative charge relative to the etching bath of 0.2-1.5 V, more preferably 0.5-1.0 V, especially when the metals to be removed in the etching bath are aluminum and/or titanium.

As described above, in the case of an SHJ solar cell with a TCO layer, the self-passivating outer layer may be present directly atop the TCO layer, or it is alternatively possible for there to be one or more additional layers between the self-passivating outer layer and the TCO layer. If etching treatment is effected and there are one or more additional layers between the self-passivating outer layer and the TCO layer, these additional layers are preferably likewise removed by the etching treatment, such that the TCO layer of the SHJ solar cell is at least partly exposed.

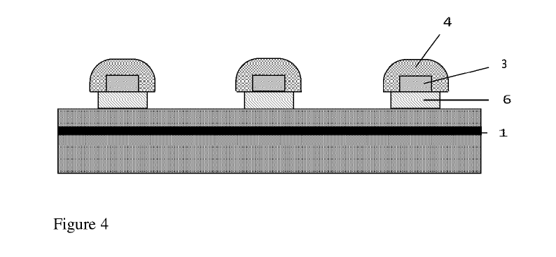

An illustrative structure in which the lateral structuring is effected by forming openings between the regions 6 of the self-passivating metal or semiconductor that still remain after the etching treatment is shown in FIG. 4. The electrically conductive seed layer 3 is present in the regions 6 that still remain. This electrically conductive seed layer 3 is covered by the galvanically deposited metal layer 4. The regions 6 preferably lie directly atop the TCO layer of the SHJ solar cell 1. The TCO layer is thus preferably at least partly exposed by the etching treatment. If the self-passivating outer layer has been applied directly atop the TCO layer of the solar cell during the production process, the regions 6 consist of this self-passivating metal or semiconductor. If multiple layers have been provided on the TCO layer of the solar cell, each of the regions 6 also has a corresponding layer structure. In this case, the uppermost layer of any region 6 is formed by the metal or semiconductor of the self-passivating outer layer and is in direct contact with the seed layer.

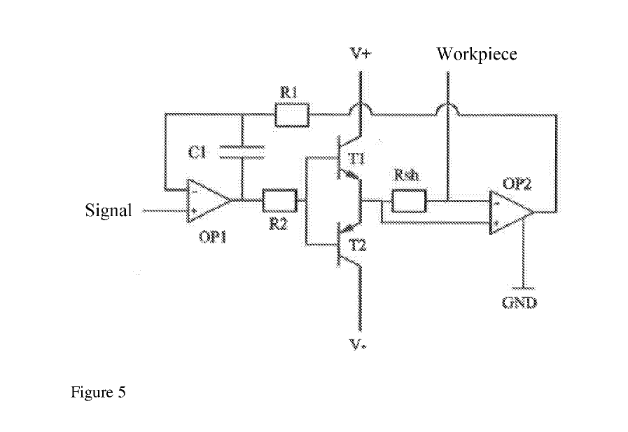

The supply of a potential with periodically changing sign to a workpiece to be galvanically coated in the electrolytic bath can be implemented by measures known to those skilled in the art. This is implemented, for example, by the circuit shown in FIG. 5: the operational amplifier OP1, with its output, actuates the push-pull stage, consisting of the npn (Darlington) transistor T1 and the pnp (Darlington) transistor T2. The differential amplifier OP2, which measures the voltage drop at the shunt resistor Rsh, attenuated by means of an RC circuit (C1, R1, R2), is fed back to the inverting output of OP1. If the chosen amplitudes of the positive potential, defined by V+, and those of the negative potential, defined by V−, are sufficiently large, the current is defined by the voltage signal at the non-inverting input of OP1, since OP1 compares this signal with the voltage drop at the shunt resistor Rsh and actuates the push-pull stage in such a way that the voltage drop caused by the current at Rsh is equal to the signal voltage. The amplitudes of the signal voltage divided by the shunt resistance thus give the amplitudes of the current through the workpiece unless the voltages V+ and V− are limiting. Preferably, during the supply of the workpiece with a negative potential, the voltage V+ chosen is sufficiently high that the defined current is attained.

As already described above, the effect of the use of a self-passivating outer layer is that the galvanic deposition is effected predominantly on the seed layer and not on the exposed regions (i.e. those not covered by the seed layer) of the self-passivating outer layer. Even if the self-passivating outer layer has a defect or is damaged prior to the galvanic deposition, a thin oxide layer automatically forms again, which closes this defect. This is advantageous over a process in which the procedure is, for example, as follows:

A non-self-passivating metal layer (e.g. Cu or Ag) is applied to the assembly. Subsequently, a thin dielectric layer is applied to said non-self-passivating metal layer, for example by oxidation of the metal surface or by application of a separate dielectric material such as Al₂O₃ or SiO₂ (e.g. by sputtering). This is then followed by the application of a structured seed layer via a non-galvanic process step, and the galvanic deposition of a metal on the seed layer. If, however, the dielectric layer should be defective, this defect is not automatically healed by the non-self-passivating metal beneath. In the course of galvanic treatment, there is therefore not just metal deposition on the structured seed layer, but also deposition of significant amounts of the metal in the region of the defect.

The present invention also relates to an apparatus obtainable by means of the process described above.

The present invention also relates to a device comprising
an assembly having a front side and a backside, wherein, on the front side and/or backside of the assembly, there is a laterally structured coating that has metallic or semiconductive regions of a self-passivating metal or semiconductor at defined intervals,
an electrically conductive seed layer present atop the metallic or semiconductive regions of the laterally structured coating,
a galvanically deposited metal layer that covers the seed layer.

The lateral structuring of the coating of the assembly results from the presence of the regions of self-passivating metal or semiconductor in lateral direction, i.e. parallel to the surface of the front side or backside, at defined distances.

With regard to preferred assemblies, reference may be made to the details above. Thus, the assembly is, for example, an electrical component (e.g. an optoelectronic component or a semiconductor component, especially a solar cell) or a precursor of a printed circuit board. A preferred electrical component is, for example, a solar cell, a diode (e.g. a light-emitting diode) or a display screen, especially a flat panel display, e.g. a liquid-crystal display “LCD”. In the case of a solar cell, the front side is the illuminated side, i.e. that facing the radiation source, of the assembly. A particularly preferred solar cell is an SHJ solar cell.

In the laterally structured coating, there may be oxidic regions between each of the metallic or semiconductive regions. The oxidic regions preferably each extend across the entire thickness or height of the laterally structured coating. The oxidic region is formed by an oxide of the self-passivating metal or semiconductor (i.e., for example, an aluminum oxide or a silicon oxide). In this case, metallic or semiconductive regions and oxidic regions thus alternate in lateral direction. As already described above, the oxidic regions can be created during the galvanic metal deposition using a pulsed current with changing sign. In the regions of the outer layer in which the structured seed layer has been applied and which therefore do not come into contact with the electrolytic bath, there is essentially no oxidation, and the metallic or semiconductive structure remains intact in these regions.

As an alternative to the oxidic regions, an opening (i.e. a solids-free region) may be present between each of the metallic or semiconductive regions in the laterally structured coating. As already described above, these openings result from an etching step which is conducted after the galvanic metal deposition. Preferably, the opening extends across the entire thickness or height of the laterally structured coating. The opening thus has a depth corresponding to the thickness of the coating.

If the assembly is an electrical component, for example a solar cell (preferably an SHJ solar cell), a diode (e.g. LED) or a display screen (e.g. LCD), the laterally structured coating preferably has a thickness of not more than 200 nm, preferably not more than 100 nm, e.g. 5-100 nm or 5-50 nm. Preferably, the laterally structured coating has the above-specified layer thickness over at least 90% of its area, more preferably over 95% of its total area. The layer thickness can be determined via standard methods, e.g. by microscopy measurement in cross section.

The metallic or semiconductive regions of the laterally structured coating, in the case of a solar cell, may have, for example, a width in the range from 10 μm to 80 μm, more preferably 10 μm to 50 μm, and may be present, for example, at distances from one another of 0.5 mm to 2.5 mm.

As already mentioned above, self-passivating metals or semiconductors are those metals or semiconductors that can spontaneously form a passivating, very thin oxide layer under air at room temperature (25° C.). Suitable self-passivating metals are especially aluminum, titanium, nickel, chromium or zinc or an alloy of one of these metals. The self-passivating metal may be in elemental form or in the form of an alloy. A preferred self-passivating semiconductor is silicon. In the oxidic regions, an oxide of the self-passivating metal or semiconductor is present.

As described above in the context of the production process, it is also possible for two or more layers of self-passivating metals or semiconductors and/or at least one layer of a non-self-passivating metal (e.g. Ag, Cu or Pd or an alloy of one of these metals) to be applied, under the condition that the outermost layer is a self-passivating layer. In this case, the metallic or semiconductive regions of the laterally structured coating may comprise two or more self-passivating metals or semiconductors and/or one or more non-self-passivating metals. In that case, the metallic or semiconductive regions have a layer structure, and the uppermost layer in direct contact with the seed layer contains the metal or semiconductor of the self-passivating outer layer. For example, the metallic or semiconductive regions contain at least one first layer of Ti, Ni, Cr or Zn or an alloy of one of these metals or Si and a second layer of Al, where one of these layers is in direct contact with the seed layer. It is optionally also possible for there to be one or more layers of a non-self-passivating metal (e.g. Cu, Ag or Pd) in these regions.

In the case of a solar cell, especially an SHJ solar cell, the metallic or semiconductive regions of the laterally structured coating may be present, for example, atop a TCO layer and be separated from one another either by openings (in the case of an etching treatment) or by oxidic regions (as a result of the pulsed current treatment and/or the aftertreatment in an anodization bath).

In an illustrative embodiment, the assembly is an SHJ solar cell containing a TCO layer (e.g. an ITO layer), wherein the laterally structured coating is present atop the TCO layer, there are openings between the metallic or semiconductive regions in the laterally structured coating, and the openings extend across the entire thickness of the laterally structured coating, such that the TCO layer is exposed in the regions of the openings.

Preferably, the seed layer is present essentially only atop the metallic or semiconductive regions, and not atop the oxidic regions. Preferably, the surface of the oxidic regions is covered essentially neither with the electrically conductive seed layer nor with the galvanically deposited metal layer.

If the component is the precursor of a printed circuit board, the laterally structured coating preferably has a thickness of ≤25 μm, more preferably ≤10 μm, even more preferably ≤1.0 μm. Layer thickness can be determined by standard methods, for example by microscope analysis in cross section.

As set out above, the device contains an electrically conductive seed layer present atop the metallic or semiconductive regions of the laterally structured coating.

With regard to suitable materials for the electrically conductive seed layer, reference may be made to the details above. As electrically conductive component, the seed layer contains, for example, one or more metals (e.g. copper or a copper alloy, a precious metal or a precious metal alloy such as silver or a silver alloy, nickel or a nickel alloy (e.g. a nickel-vanadium alloy), indium or an indium alloy, tin or a tin alloy, cobalt or a cobalt alloy), one or more electrically conductive polymers (e.g. poly-3,4-ethylenedioxythiophene (PEDOT) or a mixture of PEDOT and polystyrenesulfonate (PEDOT:PSS)), one or more electrically conductive carbon materials (e.g. graphene, graphene oxide, carbon nanotubes, graphite, carbon black) or a mixture of at least two of these components.

The electrically conductive component of the seed layer may take the form, for example, of particles (e.g. metal particles or carbon particles). These electrically conductive particles may be embedded into an organic or inorganic carrier material, for example an organic polymer. The organic polymer may be a thermoplastic or alternatively a crosslinkable or, after curing, a crosslinked polymer. For example, the electrically conductive particles of the seed layer are present in a synthetic resin that cures (for example by thermal treatment and/or UV treatment) after the application of the seed layer via the printing method. Suitable organic or inorganic carrier materials that can be used in a printing method are known to those skilled in the art. A seed layer of electrically conductive particles embedded into an organic or inorganic carrier material can particularly advantageously be applied via a printing method.

Alternatively, in a preferred embodiment, it is also possible that the seed layer is formed by a zinc layer (for example via a locally conducted zincate treatment) and a layer of electroless nickel applied to said zinc layer.

As a result of the self-passivation, a thin oxide layer may be present between the metallic or semiconductive regions of the laterally structured coating and the seed layer applied thereto. Since this thin oxide layer, however, may have been removed again in these regions for process-related reasons during the application of the seed layer (for example by a LIFT method), it is also possible that the metallic or semiconductive regions and the seed layer applied thereto directly adjoin one another.

The electrically conductive seed layer is preferably in the form of one or more conductor tracks.

The seed layer preferably has a thickness of ≤20 μm, more preferably ≤8 μm, even more preferably ≤2 μm. The minimum thickness of the seed layer is, for example, 100 nm. Preferably, the seed layer has the above-specified layer thickness across at least 80% of its area, preferably across its entire area. Layer thickness can be determined by standard methods, for example by microscope analysis in cross section or transverse section.

The structured seed layer may be mono- or multilaminar. If the seed layer is multilaminar, it is formed from two or more superposed laminas, where each lamina may have been manufactured from one or more of the materials mentioned above.

As already described above, a multilaminar seed layer contains, for example, an electrically conductive metal layer that results from a gas phase deposition, and applied thereto an electrically conductive layer that has been obtained via a printing method, a laser transfer method or an electroless electrochemical deposition.

As set out above, the device also contains a galvanically deposited metal layer that covers the seed layer. Preferably, the seed layer is completely covered by the galvanically deposited metal layer, i.e. including the flanks that laterally bound the seed layer. Complete coverage of the seed layer with the galvanically deposited metal is advantageous since this results in effective protection of the seed layer in the finished product from oxidation, moisture or other chemical attack by the electrolytic layer.

The electrolytically deposited metal is preferably copper or a copper alloy, nickel or a nickel alloy or a precious metal such as silver or a silver alloy.

The device is preferably obtainable via the process described above.

The present invention also relates to a device comprising
an assembly having a front side and a backside, wherein the front side and/or the backside of the assembly is formed by a coating of a transparent conductive oxide (TCO coating),
an electrically conductive seed layer applied in defined regions atop the TCO coating,
a galvanically deposited metal layer that covers (preferably completely covers) the seed layer.

With regard to the preferred properties of the TCO coating, the electrically conductive seed layer and the electrolytically deposited metal layer, reference may be made to the above remarks.

The assembly is preferably an electrical component (e.g. an optoelectronic component or a semiconductor component, especially a solar cell). A preferred electrical component is, for example, a solar cell, a diode (e.g. a light-emitting diode) or a display screen, especially a flat panel display, e.g. a liquid-crystal display “LCD”. In the case of a solar cell, the front side is the illuminated side, i.e. that facing the radiation source, of the assembly. A particularly preferred solar cell is an SHJ solar cell.

Preferably, the surface of the TCO coating is essentially not covered by the galvanically deposited metal layer.

The invention is described in further detail by the following examples.

### EXAMPLE 1

### Applying Electrical Contacts to a Carrier Material of Plastic for Production of a Printed Circuit Board

The assembly used is a plastic sheet to which a thin (1 μm) aluminum coating has been applied as outer layer. The aluminum coating has been adhesive-bonded as a foil. If necessary, via holes can be drilled to inner conductor tracks or conductor tracks on the other side. Since aluminum is a self-passivating metal, a thin, passivating oxide film will inevitably form on the outer layer.

A silver particle-containing paste with a volatile solvent is applied to the aluminum layer by means of screenprinting with the pattern of the desired conductor tracks. The workpiece is then heated to 100° C. for 5 min in order to drive the solvent out of the paste. Thus, a structured, electrically conductive seed layer is obtained on defined regions of the outer layer.

In a copper electrolyte bath in sulfuric acid with a sacrificial Cu anode, the structured seed layer and the aluminum layer are supplied with a periodically changing potential (i.e. use of a pulsed current with cathodic (negative) and anodic (positive) current pulses). Under cathodic potential, galvanic deposition of the copper takes place on the seed layer. To a small degree, copper crystallites are also deposited on the passivated surface of the outer aluminum layer. Under anodic potential, there is a certain degree of dissolution of the copper already deposited. However, this primarily affects the copper deposited on the passivated aluminum surface, while the dissolution of copper in the region of the seed layer is not a significant consideration. The amplitude of the cathodic current density is 10 A/dm². In this case, the area in respect of the current density relates to the area of the seed layer. The amplitude of the anodic current density is likewise 10 A/dm², but based on the total area.

In order to electrically separate the conductor tracks from one another after galvanic copper deposition, the plastic sheet is wetted over the whole area with concentrated hydrochloric acid as etching medium, such that the exposed regions of the aluminum layer (i.e. the regions of the aluminum layer not covered by the metal-coated seed layer) are removed by the etching medium. This likewise removes a portion of the galvanically deposited metal. However, this can be compensated for by applying a correspondingly high layer thickness in the electrolytic bath and/or the etching medium HCl is chosen such that the galvanically deposited copper layer is etched to a far lesser degree than the aluminum surface.

### EXAMPLE 2

### Applying Electrical Conductor Tracks to a Silicon Heterojunction Solar Cell (SHJ Solar Cell)

The assembly used is a customary SHJ solar cell with an edge length of 156 mm×156 mm. As an integral constituent, this SHJ solar cell already has an ITO layer on its front side. The ITO layer functions as outer layer of the assembly, to which the electrical conductor tracks have to be applied. The ITO layer has a sheet resistance of 100Ω across its entire area.

Electrolytic deposition of copper on ITO is inhibited at low applied voltages of less than 1V. This can be explained as follows: ITO is a highly doped electron conductor, meaning that the conduction band is partly populated by electrons, whereas there are virtually no holes in the valence band. The chemical potential of ITO is about −4.3 eV. The chemical potential of a copper electrolyte is much lower (about −5 eV to −6 eV). As a result, on contact of ITO with a copper electrolyte, there is transfer of electrons from the ITO surface into the electrolyte. This causes an electrical potential difference between ITO and electrolyte. Since the charge carrier density in the electrolyte is much higher than in the ITO, there is only a small drop in the potential in the electrolyte over a distance of a few Ångströms, whereas the majority of the drop in the potential in the ITO, depending on the doping, is over a distance of 5-100 nm. In the region of the potential drop in the ITO, there are virtually no electrons in the conduction band any longer. Electron transfer through the ITO surface is thus greatly inhibited.

By means of screenprinting, a silver particle-containing paste is applied to the ITO layer with the pattern of the desired conductor tracks. Thus, a structured, electrically conductive seed layer is obtained in defined regions of the outer ITO layer.

The solar cell is then moved through an electrolytic bath containing a copper electrolyte with wetting on the front side, while a metal sliding contact is attached on the backside. Since, in the example chosen, the phosphorus-doped amorphous silicon layer of the SHJ solar cell is on the front side, the solar cell is illuminated through the electrolyte bath, such that the electrical current, in the case of application of cathodic voltage on the backside, can get to the front side of the solar cell.

The solar cell is then supplied with cathodic voltage for 4 ms and with anodic voltage for 1 ms in a periodically alternating manner for about 5 min. Under cathodic voltage, the current is limited to 500 mA and the voltage to 2 V, and under anodic voltage to 800 mA and 2 V. This is controlled by corresponding electronics; see FIG. 4.

The galvanic deposition of copper is effected on the structured seed layer formed by the silver paste.

### EXAMPLE 3

### Applying Electrical Conductor Tracks to a Bifacial Silicon Heterojunction Solar Cell

An SHJ solar cell having an ITO layer both on its front side and on its backside is used. By sputtering, an outer aluminum layer (i.e. a layer of a self-passivating metal) with a thickness of about 20 nm is applied to each of the two ITO layers.

By laser transfer, a seed layer of nickel in the form of a grid is applied to the self-passivating layer of aluminum. Thus, a structured, electrically conductive seed layer is obtained in defined regions of the outer aluminum layer. The structured nickel seed layer is applied both to the front side and to the backside of the assembly.

The SHJ solar cell is then provided with electrical contacts in the regions of the seed layer by means of stainless steel clips and immersed completely into an electrolytic sulfuric acid bath containing a copper salt. The solar cell is then supplied with cathodic voltage for 9 ms and with anodic voltage for 1 ms in a periodically alternating manner for about 5 min. Under cathodic voltage, a current of 800 mA flows; under anodic voltage, a maximum current of 1600 mA and a maximum voltage V+ of 10 V are defined. This is controlled by the above-elucidated circuit shown in FIG. 4.

Copper is galvanically deposited atop the structured nickel seed layer. Then the pulse parameters are finally adjusted for the complete oxidation of the aluminum layer: the amplitude of the anodic current is set to 5 A and that of the voltage to 10 V. The duration of the pulse is 5 ms. The amplitude of the cathodic voltage is set to 0.9 V and that of the current to 2 A. The duration of the anodic pulse is likewise 5 ms. With these parameters, the sample is treated in the electrolyte bath for 10 seconds.

By the electroplating step, copper is selectively electrolytically deposited atop the nickel seed layer. In the exposed regions, i.e. those not covered by the nickel seed layer, the outer aluminum layer is oxidized, forming aluminum oxide, which is transparent owing to its low thickness.

### EXAMPLE 4

### Production of Electrolytic Conductor Tracks on Silicon Substrates

A textured silicon substrate of layer thickness 180 μm is used. An insulating silicon oxide layer is applied to the silicon surface. Subsequently, an outer aluminum layer of thickness 1 μm is applied by vapor deposition to the full area of the silicon oxide layer. An assembly with an outer layer of self-passivating metal is thereby obtained.

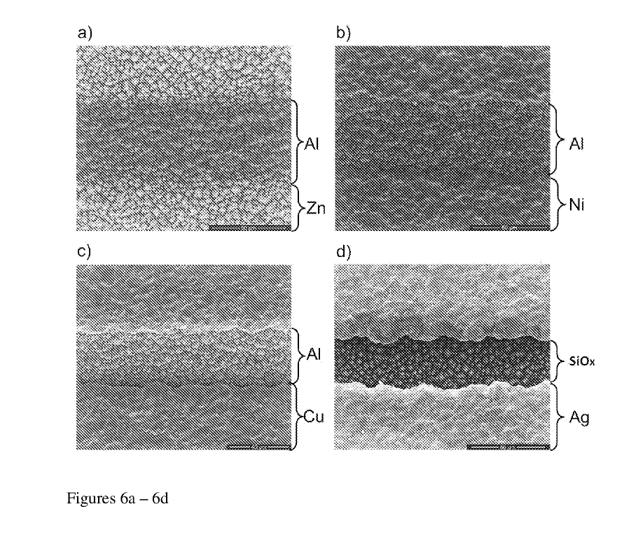

In defined regions, the outer self-passivating aluminum layer is contacted with a zincate solution via a sealing die. In these regions, a zinc layer is formed. FIG. 6a shows an SEM image of this surface after the formation of the zinc layer. Subsequently, by means of electroless plating, nickel (“electroless nickel”) is applied to the zinc layer. The nickel is deposited selectively atop the zinc, but not atop the outer aluminum layer. FIG. 6b shows an SEM image of the surface after the electroless deposition of the nickel. Thus, a structured seed layer is obtained atop the outer aluminum layer, which is formed by a zinc layer and a nickel layer deposited atop said zinc layer.

The assembly is contacted with an electrolytic bath containing a copper electrolyte. Subsequently, it is subjected periodically to cathodic and anodic voltage. Copper is deposited galvanically atop the Zn/Ni seed layer. FIG. 6c shows an SEM image of the surface after the galvanic deposition of the copper. No deposition of copper is apparent on the self-passivating outer aluminum layer. Subsequently, the assembly is contacted with an electrolytic bath containing silver electrolyte and, using a pulsed current with changing sign, silver is galvanically deposited atop the copper layer.

Finally, by an etching treatment, the exposed outer aluminum layer is removed and hence the silicon oxide layer beneath is exposed. The conductor tracks produced are now electrically separated from one another. FIG. 6d shows a microscope image of the surface after the final etching step.

There is thus a laterally structured coating on the dielectric silicon oxide layer of the assembly, having metallic regions (of aluminum) at defined distances that are separated from one another by openings. The Zn/Ni seed layer is present selectively in the aluminum regions, and this in turn is covered completely—i.e. including at the flanks that laterally bound the layer—by galvanically deposited copper and silver.

### EXAMPLE 5

### Al—Ni—Cu—Ag Conductor Tracks on Monocrystalline Silicon Wafer

An aluminum layer is applied by vapor deposition over the full area of a planar monocrystalline silicon wafer.

By means of screenprinting, a zincate-based paste is printed on locally, which is in contact for 80 seconds and is then rinsed off with water. The substrate is then immersed into an electroless nickel-phosphorus electrolyte having a pH of 4.8 for 180 seconds. This coats only the regions with which the zincate-based paste was previously in contact with nickel-phosphorus. In defined regions of the outer aluminum layer, a seed layer formed from zinc and electroless nickel is thus obtained.

This is followed by the galvanic deposition of copper atop said seed layer composed of zinc and electroless nickel. This is done using an acidic copper electrolyte based on copper sulfate with a pH of 2.8. For the deposition, a potential of 1.2 V is applied. By contrast, the negative potential leads to deposition of copper in the nickel-phosphorus regions. Likewise, in the subsequent electrolytic silver deposition from an alkaline silver electrolyte (pH 10.5), only the copper region is coated and the aluminum regions remain protected as a result of the applied potential of 1.1 V.

Subsequently, an etching step is conducted in a dilute hydrochloric acid solution. This preferentially etches the aluminum regions alongside the galvanically applied conductor tracks. The aluminum etching rate is much higher than in the case of substrates with comparably thick aluminum layers. The reason for this is the formation of a local element between aluminum and the galvanically deposited Ni/Cu/Ag layer stack, which leads to faster dissolution (corrosion) of the aluminum.

### EXAMPLE 6

### Conductor Tracks on Both Sides of Printed Circuit Board Substrate

The base substrate for this example is a printed circuit board precursor consisting of prepreg material (layer thickness 500 μm) coated on both sides with an aluminum foil (30 μm). Thin nickel layers are applied by means of a laser transfer process on both sides in defined regions of the outer aluminum layer. These are electrolytically thickened in an alkaline copper bath based on pyrophosphate (pH 8.0). Once a layer thickness of 5 μm of copper has been deposited, the aluminum is removed in a dilute sodium hydroxide solution, by which the nickel/copper regions are not attacked. As soon as the aluminum foil has been etched through across the entire layer thickness, the Al/Ni/Cu conductor tracks are electrically separated from one another.

### EXAMPLE 7

A 15 nm-thick Ti layer (i.e. a first layer of self-passivating metal) is applied as bonding layer and diffusion barrier to the ITO layer of an SHJ solar cell by means of sputtering. An 85 nm-thick Al layer is applied thereto, likewise by means of sputtering. This second layer of self-passivating metal constitutes the outer layer, atop which the structured, electrically conductive seed layer is subsequently applied via a non-galvanic deposition.

Even though the galvanic metal deposition step is effected only after the application of the seed layer, the current distribution in the galvanic process is improved when at least one of the layers of self-passivating metal is an aluminum layer.

By means of laser transfer, a nickel layer is applied in the form of the desired conductor tracks. This nickel layer constitutes the structured, electrically conductive seed layer on which the galvanic metal deposition is subsequently effected.

The nickel layer is thickened with a conductive Cu layer and a protective Ag layer with the aid of the pulsed plating method described in Example 3.

Finally, the Ti/Al layer stack is etched off in the region between the conductor tracks in 1 molar NaOH. For this purpose, a negative voltage of 0.6 V relative to an auxiliary electrode in the etching bath is applied to the workpiece. The applied voltage prevents etching attack by the NaOH on the conductor tracks and the ITO layer.

1. A process for producing one or more electrical contacts on an assembly, comprising the following steps:
providing an assembly having a front side and a backside, wherein an outer layer of a transparent, electrically conductive oxide (TCO) or a self-passivating metal or semiconductor is present on the front side and/or the backside,
applying a structured, electrically conductive seed layer to defined regions of the outer layer, said seed layer being applied non-galvanically,
galvanically depositing at least one metal on the seed layer.

2. The process as claimed in claim 1, wherein the assembly is an electrical component, especially a solar cell or a light-emitting diode, or a precursor of a printed circuit board.

3. The process as claimed in claim 2, wherein the solar cell is a heterojunction solar cell.

4. The process as claimed in claim 1, wherein the TCO is an indium tin oxide (ITO), an aluminum-doped zinc oxide (AZO), a fluorine-doped tin oxide (FTO), a boron-doped zinc oxide or a hydrogen-doped indium oxide; and/or the self-passivating metal is aluminum, titanium, nickel, chromium or zinc or an alloy of one of these metals, or the self-passivating semiconductor is silicon.

5. The process as claimed in claim 1, wherein the assembly has a TCO layer and there are one or more additional layers of a metal or semiconductor between the TCO layer and the self-passivating outer layer.

6. The process as claimed in claim 1, wherein the assembly has a TCO layer and the self-passivating outer layer is present directly atop the TCO layer.

7. The process as claimed in claim 1, wherein the assembly has a TCO layer and at least two layers of self-passivating metal or semiconductor on the front side and/or backside of the assembly and the outer of these self-passivating layers forms the outer layer.

8. The process as claimed in claim 7, wherein the metal or semiconductor of the first self-passivating layer is titanium, nickel, chromium or zinc or an alloy of one of these metals or silicon, and the second self-passivating layer is an aluminum layer that forms the outer layer.

9. The process as claimed in claim 7, wherein the assembly has at least three layers of self-passivating metal or semiconductor, wherein the metal or semiconductor of the first self-passivating layer is titanium, nickel, chromium or zinc or an alloy of one of these metals or silicon, the second self-passivating layer is an aluminum layer, the third self-passivating layer is present as the outer layer and the metal or semiconductor in this third self-passivating layer is titanium, nickel, chromium or zinc or an alloy of one of these metals or silicon.

10. The process as claimed in claim 7, wherein the first self-passivating layer is present directly atop the TCO layer or there is at least one layer of a non-self-passivating metal between the first self-passivating layer and the TCO layer.

11. The process as claimed in claim 1, wherein the outer layer of the self-passivating metal or semiconductor is obtained via a physical vapour phase deposition, a chemical vapour phase deposition or by application of a foil of the self-passivating metal or semiconductor; and/or wherein the outer layer of the assembly has a thickness of 25 μm.

12. The process as claimed in claim 1, wherein the seed layer is applied to defined regions of the outer layer via a printing process, a laser transfer process or an electroless electrochemical deposition.

13. The process as claimed in claim 1, wherein the structured seed layer is multilaminar and the applying of the structured seed layer comprises the following steps:
applying an electrically conductive metal layer S1 via a vapour phase deposition,
applying an electrically conductive layer S2 to defined regions of the metal layer S1 by a printing process, a laser transfer process or an electroless plating,
removing the exposed regions of the metal layer S1 that are not covered by the layer S2.

14. The process as claimed in claim 1, wherein the electrically conductive seed layer comprises one or more metals, one or more electrically conductive polymers, one or more electrically conductive carbon materials, or a mixture of at least two of these components; and/or wherein the seed layer has a thickness of ≤20 μm.

15. The process as claimed in claim 1, wherein the galvanically deposited metal is copper or a copper alloy, nickel or a nickel alloy or a precious metal.

16. The process as claimed in claim 1, wherein the galvanic deposition of the metal is effected by means of pulsed current with cathodic and anodic pulses.

17. The process as claimed in claim 1, wherein the galvanic deposition of the metal is followed by an anodization of the self-passivating metal or semiconductor in an anodization bath.

18. The process as claimed in claim 1, wherein the galvanic deposition is followed by removal of exposed regions of the outer layer that are not covered by the structured seed layer by an etching treatment.

19. The process as claimed in claim 18, wherein the etching treatment is effected in an etching bath and the assembly is charged with a negative voltage relative to the etching bath.

20. A device comprising:
an assembly having a front side and a backside, wherein, on the front side and/or backside of the assembly, there is a laterally structured coating that has metallic or semiconductive regions of a self-passivating metal or semiconductor at defined intervals,
an electrically conductive seed layer present atop the metallic or semiconductive regions of the laterally structured coating,
a galvanically deposited metal layer that covers the seed layer.

21. The device as claimed in claim 20, wherein, between each of the metallic or semiconductive regions in the laterally structured coating, there are openings or oxidic regions that extend across the entire thickness of the coating.

22. The device as claimed in claim 21, wherein the surface of the oxidic regions is essentially covered neither with the electrically conductive seed layer nor with the galvanically deposited metal layer.

23. The device as claimed in claim 20, wherein the assembly is an SHJ solar cell comprising a TCO layer and the laterally structured coating is present atop the TCO layer, wherein there are openings in the laterally structured coating between the metallic or semiconductive regions, and the openings extend across the entire thickness of the laterally structured coating, such that the TCO layer is exposed in the regions of the openings.

24. A device comprising:
an assembly having a front side and a backside, wherein the front side and/or the backside of the assembly is formed by a coating of a transparent conductive oxide (TCO coating),
an electrically conductive seed layer applied in defined regions atop the TCO coating,
a galvanically deposited metal layer that covers the seed layer.
